(19) United States
(12) Patent Application Publication
(10) Pub. No.: US 2025/0386654 A1
(43) Pub. Date: Dec. 18, 2025

(54) MICRO LED PIXEL AND MICRO LED DISPLAY PANEL

(71) Applicant: JADE BIRD DISPLAY (SHANGHAI) LIMITED, SHANGHAI (CN)

(72) Inventors: Weisin TAN, Shanghai (CN); Qunchao XU, Shanghai (CN)

(21) Appl. No.: 19/235,606

(22) Filed: Jun. 12, 2025

(30) Foreign Application Priority Data
Jun. 14, 2024 (WO) PCT/CN2024/099247

(51) Int. Cl. H10H 29/85; H10H 29/80

(52) U.S. Cl. CPC H10H 29/857; H10H 29/942; H10H 29/962

(57) ABSTRACT

A polychrome micro LED pixel includes at least two light emitting structures, and each of the at least two light emitting structures includes at least two sub-pixels. A micro LED display panel includes an integrated circuit (IC) backplane including a bottom pad array, the bottom pad array including a plurality of groups of bottom pads; and a micro LED array formed on the IC backplane, the micro LED array including a plurality of polychrome micro LED pixels. One micro LED pixel of the plurality of micro LED pixels is electrically connected with one group of bottom pads of the plurality of groups of bottom pads.

### CROSS-REFERENCE TO RELATED APPLICATIONS

The present disclosure claims the benefit of priority to PCT Application No. PCT/CN2024/099247, filed on Jun. 14, 2024, which is incorporated herein by reference in its entirety.

### TECHNICAL FIELD

The present disclosure generally relates to micro LED manufacturing technology, and more particularly, to a micro LED pixel and a micro LED display panel.

### BACKGROUND

Inorganic micro pixel light emitting diodes (LEDs), also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density. Pixel yield that refers to a percentage of viable or useable pixels in a display panel, is an important index for a micro LED display panel.

However, low pixel yield is a problem for the micro LED pixels.

### SUMMARY OF THE DISCLOSURE

Embodiments of the present disclosure provide a polychrome micro LED pixel. The polychrome micro LED pixel includes at least two light emitting structures, and each of the at least two light emitting structures includes at least two sub-pixels.

Embodiments of the present disclosure also provide a micro LED display panel. The micro LED display panel includes an integrated circuit (IC) backplane including a bottom pad array, the bottom pad array including a plurality of groups of bottom pads; and a micro LED array formed on the IC backplane, the micro LED array including a plurality of polychrome micro LED pixels. One micro LED pixel of the plurality of micro LED pixels is electrically connected with one group of bottom pads of the plurality of groups of bottom pads.

Embodiments of the present disclosure further provide a monochrome micro LED pixel. The monochrome micro LED pixel includes at least two sub-pixels, and the at least two sub-pixels are controlled by the same control signal.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a top view of an exemplary polychrome micro LED pixel, according to some embodiments of the present disclosure.

FIG. 2A to FIG. 2D illustrate exemplary arrangements of sub-pixels of a light emitting structure, according to some embodiments of the present disclosure.

FIG. 3A illustrates a structural diagram showing a side view of an exemplary polychrome micro LED pixel, according to some embodiments of the present disclosure.

FIG. 3B illustrates a structural diagram showing a top view of the exemplary polychrome micro LED pixel shown in FIG. 3A, according to some embodiments of the present disclosure.

FIG. 4 illustrates a structural diagram showing a top view of another exemplary polychrome micro LED pixel, according to some embodiments of the present disclosure.

FIG. 5 illustrates a structural diagram showing a side view of another exemplary polychrome micro LED pixel, according to some embodiments of the present disclosure.

FIG. 6A illustrates a structural diagram showing a side view of another exemplary polychrome micro LED pixel, according to some embodiments of the present disclosure.

FIG. 6B illustrates a structural diagram showing a top view of an exemplary light emitting structure of the polychrome micro LED pixel shown in FIG. 6A, according to some embodiments of the present disclosure.

FIG. 7 illustrates a structural diagram showing a top view of an exemplary monochrome micro LED pixel, according to some embodiments of the present disclosure.

FIG. 8 illustrates a structural diagram showing a top view of an exemplary micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a polychrome micro LED pixel having redundant pixels. A polychrome micro LED pixel includes at least two light emitting structures, and each of the at least two light emitting structures may include at least two sub-pixels. Therefore, when one sub-pixel does not operate, another sub-pixel can still emit light, which can substantially reduce random single pixel failures.

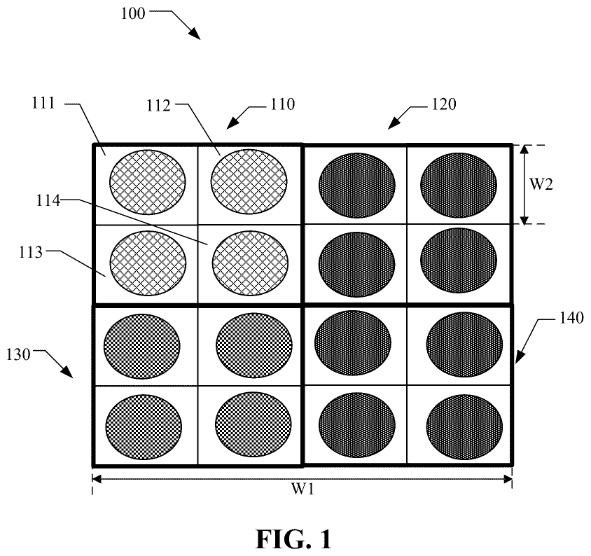

FIG. 1 illustrates a structural diagram showing a top view of an exemplary polychrome micro LED pixel 100, according to some embodiments of the present disclosure. As shown in FIG. 1, polychrome micro LED pixel 100 includes four light emitting structures 110, 120, 130 and 140. Each of the light emitting structures includes four sub-pixels. For example, light emitting structure 110 includes four sub-pixels 111, 112, 113, and 114. In this example, light emitting structure 110 emits green light, light emitting structure 130 emits blue light, and light emitting structures 120 and 140 emit red light. The sub-pixels in the same light emitting structure emit light with the same color. For example, since light emitting structure 110 emits green light, all of the four sub-pixels 111, 112, 113, and 114 of light emitting structure 110 emit green light. In some embodiments, the sub-pixels are controlled by the same control signal. That is, if one sub-pixel does not operate, the other sub-pixels of the same light emitting structure can still emit light based on the control signal, so that the light emitting efficiency is improved. In some embodiments, polychrome micro LED pixel 100 is provided on an integrated circuit (IC) backplane, and is controlled by an external circuit through the IC backplane. All the sub-pixels of the same light emitting structure may connect to the same bottom pad on the IC backplane for receiving control signals.

Still referring to FIG. 1, in some embodiments, each sub-pixel is square. The four sub-pixels 111, 112, 113, and 114 are arranged on the same horizontal plane, and the four sub-pixels are arranged in a 2×2 array. The horizonal plane is a plane that is in parallel with a plane in which the IC backplane is located. A vertical plane is a plane that is perpendicular to the plane in which the IC backplane is located. For example and without limitation, exemplary dimensions of polychrome micro LED pixel 100 include a width W1 of 4 μm, and for a sub-pixel 111, a width W2 of 1 μm. In this example, only for illustrative purpose, four light emitting structures are arranged in a 2×2 array and the four sub-pixels of each light emitting structure are arranged in a 2×2 array.

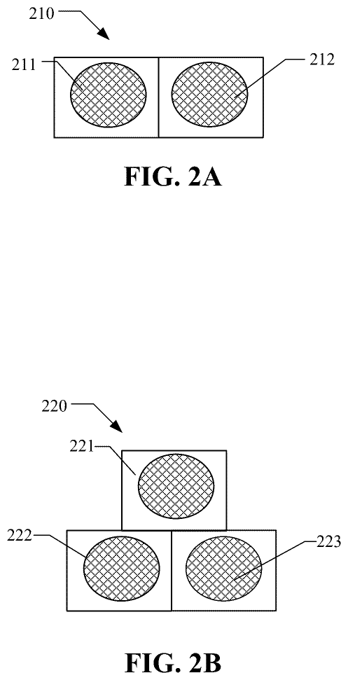

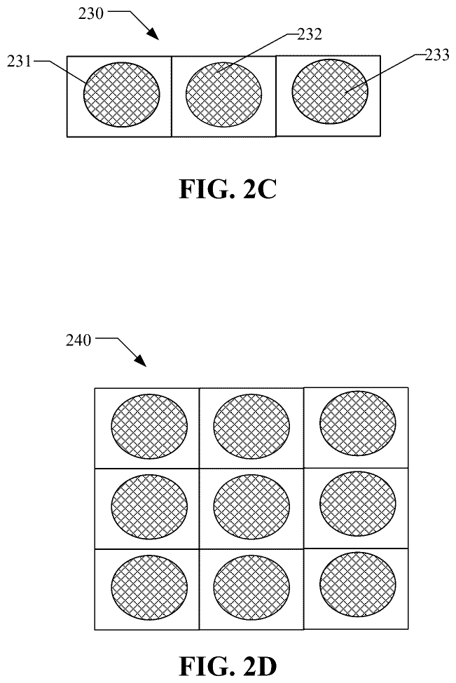

FIG. 2A to FIG. 2D illustrate exemplary arrangements of sub-pixels of a light emitting structure, according to some embodiments of the present disclosure. In some embodiments, each sub-pixel is square. Referring to FIG. 2A, a light emitting structure 210 includes two sub-pixels 211 and 212 arranged side by side. Referring to FIG. 2B, a light emitting structure 220 includes three sub-pixels 221, 222, and 223 arranged in a triangular configuration. Referring to FIG. 2C, a light emitting structure 230 includes three sub-pixels 231, 232, and 233 arranged in a line. Referring to FIG. 2D, a light emitting structure 240 includes nine sub-pixels arranged in a 3×3 array. It can be understood that in other embodiments, the at least two emitting structures and the at least two sub-pixels can be arranged in other forms, which is not limited herein.

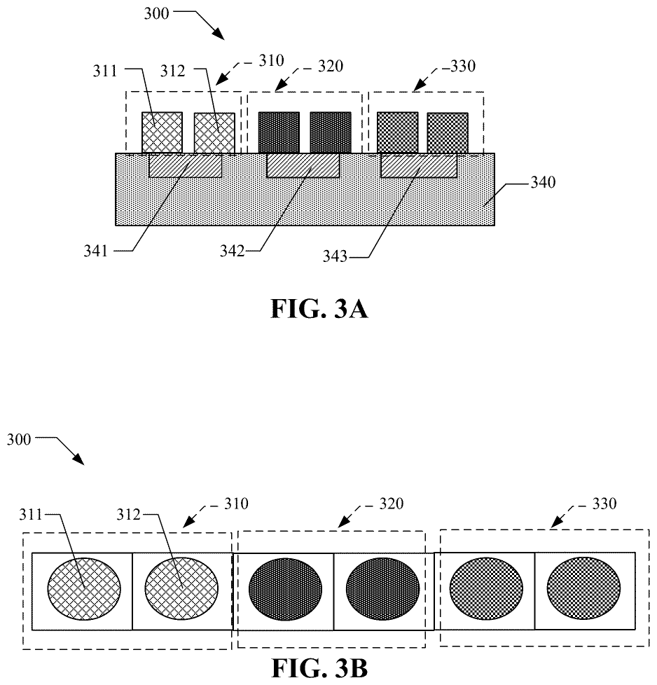

FIG. 3A illustrates a structural diagram showing a side view of an exemplary polychrome micro LED pixel 300, according to some embodiments of the present disclosure. FIG. 3B illustrates a structural diagram showing a top view of exemplary polychrome micro LED pixel 300 shown in FIG. 3A, according to some embodiments of the present disclosure. As shown in FIGS. 3A and 3B, polychrome micro LED pixel 300 includes a first light emitting structure 310, a second light emitting structure 320, and a third light emitting structure 330. The three light emitting structures (i.e., 310, 320, and 330) are arranged along a horizontal direction. The horizontal direction is a direction that is in parallel to a plane in which the IC backplane 340 is located. A vertical direction is a direction that is perpendicular to the plane in which the IC backplane 340 is located. Each light emitting structure may include two sub-pixels. For example, first light emitting structure 310 includes a first sub-pixel 311 and a second sub-pixel 312. First sub-pixel 311 and second sub-pixel 312 are arranged along the same direction, i.e., along the same lines, along which the three light emitting structures 310, 320, and 330 are arranged. As a result, all the sub-pixels of polychrome micro LED pixel 300 are arranged along the same line, as shown in FIGS. 3A and 3B. Referring to FIG. 3A, first sub-pixel 311 and second sub pixel 312 of first light emitting structure 310 are connected to a common bottom pad 341 on IC backplane 340 for receiving the same control signal. It can be understood that sub-pixels of second light emitting structure 320 are connected to a common bottom pad 342, and sub-pixels of third light emitting structure 330 are connected to a common bottom pad 343. In some embodiments, first light emitting structure 310 emits red light, second light emitting structure 320 emits green light, and third light emitting structure 330 emits blue light. Therefore, first sub-pixel 311 and second-sub pixel 312 emit red light, the sub-pixels of second light emitting structure 320 emit green light, and the sub-pixels of third light emitting structure 330 emit blue light.

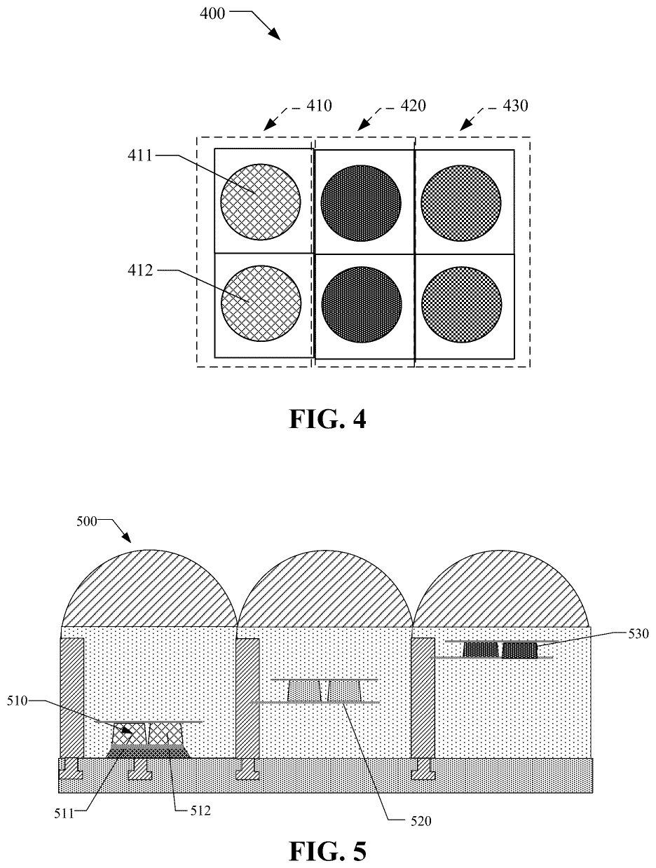

FIG. 4 illustrates a structural diagram showing a top view of another exemplary polychrome micro LED pixel 400, according to some embodiments of the present disclosure. As shown in FIG. 4, polychrome micro LED pixel 400 includes a first light emitting structure 410, a second light emitting structure 420, and a third light emitting structure 430. The three light emitting structures (i.e., 410, 420, and 430) are arranged in a horizontal direction. Each light emitting structure may include two sub-pixels. For example, first light emitting structure 410 includes a first sub-pixel 411 and a second sub pixel 412. First sub-pixel 411 and second sub-pixel 412 are arranged along a direction that is perpendicular to a direction along which the three light emitting structures arranged, and all the sub-pixels of polychrome micro LED pixel 400 are arranged in an array, as shown in FIG. 4. Description of other features of polychrome micro LED pixel 400 may be found by referring to corresponding features described above with reference to FIG. 3A, which will not be repeated here.

FIG. 5 illustrates a structural diagram showing a side view of another exemplary polychrome micro LED pixel 500, according to some embodiments of the present disclosure. As shown in FIG. 5, polychrome micro LED pixel 500 includes a first light emitting structure 510, a second light emitting structure 520, and a third light emitting structure 530. The three light emitting structures (i.e., 510, 520, and 530) are stacked in a vertical direction. In this example, the light emitting structures are also staggered in the vertical direction. That is, one light emitting structure is not covered by another in the vertical direction. In some embodiments, first light emitting structure 510, i.e., the bottom-most light emitting structure, emits red light, second light emitting structure 520 emits blue light, and third light emitting structure 530, i.e., the top-most light emitting structure, emits green light. Each light emitting structure may include at least two sub-pixels. For example, first light emitting structure 510 may include at least two sub-pixels 511 and 512. Description of the arrangement of sub-pixels of light emitting structures (i.e., 510, 520, and 530) may be found by referring to the arrangements described above with reference to FIG. 2A to 2D, which will not be repeated here.

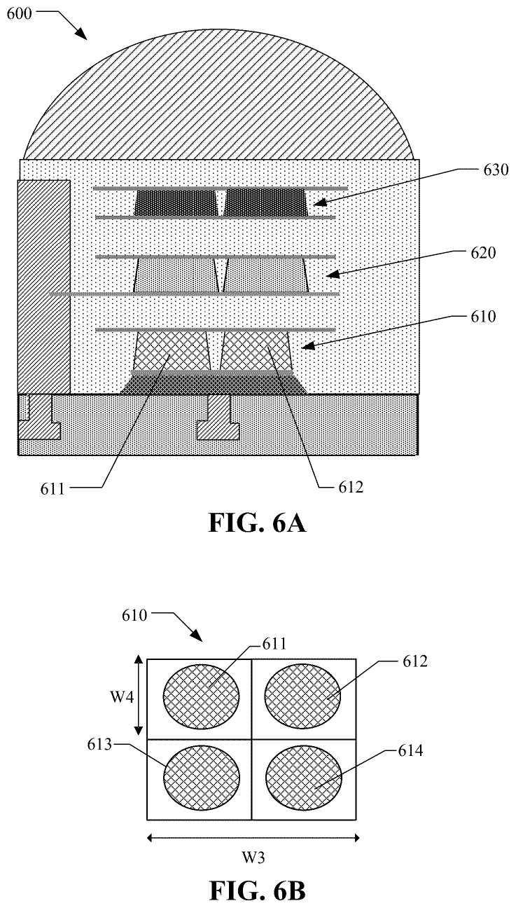

FIG. 6A illustrates a structural diagram showing a side view of another exemplary polychrome micro LED pixel 600, according to some embodiments of the present disclosure. As shown in FIG. 6A, polychrome micro LED pixel 600 includes a first light emitting structure 610, a second light emitting structure 620, and a third light emitting structure 630. The three light emitting structures (i.e., 610, 620, and 630) are stacked in a vertical direction. In this example, the light emitting structures are overlapped in the vertical direction. That is, one light emitting structure is provided over another light emitting structure. In some embodiments, first light emitting structure 610, i.e., the bottom-most light emitting structure, emits red light, second light emitting structure 620 emits blue light, and third light emitting structure 630, i.e., the top-most light emitting structure, emits green light. Each light emitting structure may include at least two sub-pixels. For example, first light emitting structure 610 may include at least two sub-pixels 611 and 612.

FIG. 6B illustrates a structural diagram showing a top view of the exemplary light emitting structure of polychrome micro LED pixel 600 shown in FIG. 6A, according to some embodiments of the present disclosure. As shown in FIG. 6B, first light emitting structure 610 may include four sub-pixels 611, 612, 613, and 614. In some embodiments, each sub-pixel is square. For example and without limitation, exemplary dimensions of polychrome micro LED pixel 600 include a width W3 of 4 μm. Therefore, for a sub-pixel 611, a width W4 of 2 μm.

Description of other arrangements of sub-pixels of light emitting structures (i.e., 610, 620, and 630) may be found by referring to the arrangements described above with reference to FIG. 2A to 2D, which will not be repeated here.

Embodiments of the present disclosure provide a monochrome micro LED pixel having redundant pixels. A monochrome micro LED pixel includes at least two sub-pixels. Therefore, when one sub-pixel does not operate, another sub-pixel can still emit light, which can substantially reduce random single pixel failures.

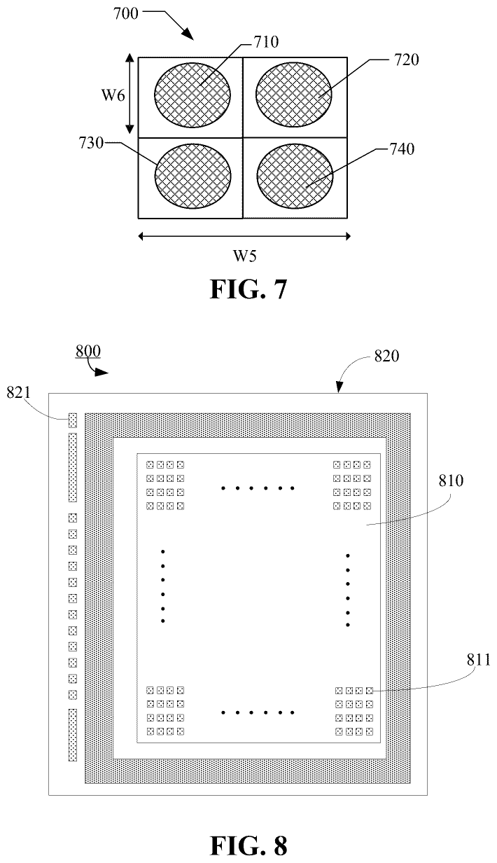

FIG. 7 illustrates a structural diagram showing a top view of an exemplary monochrome micro LED pixel 700, according to some embodiments of the present disclosure. As shown in FIG. 7, monochrome micro LED pixel 700 includes four sub-pixels 710, 720, 730, and 740. For example, monochrome micro LED pixel 700 emits red light. Four sub-pixels 710, 720, 730, and 740 emit light of the same color. In some embodiments, four sub-pixels 710, 720, 730, and 740 are controlled by the same control signal. That is, if one sub-pixel does not operate, the other sub-pixels of the same monochrome micro LED pixel can still emit light based on the control signal, so that the light emitting efficiency is improved. In some embodiments, monochrome micro LED pixel 700 is provided on an integrated circuit (IC) backplane, and is controlled by an external circuit through the IC backplane. All the sub-pixels of a monochrome micro LED pixel may connect to the same bottom pad on the IC backplane for receiving control signals.

In some embodiments, each sub-pixel is square. The four sub-pixels 710, 720, 730, and 740 are arranged on the same horizontal plane, and the four sub-pixels are arranged in a 2×2 array. The horizonal plane is a plane that is in parallel with a plane in which the IC backplane is located. A vertical plane is a plane that is perpendicular to the plane in which the IC backplane is located. For example and without limitation, exemplary dimensions of monochrome micro LED pixel 700 include a width W5 of 4 μm. Therefore, a sub-pixel 710 has a width W6 of 2 μm. In this example, only for illustrative purpose, four sub-pixels 710, 720, 730, and 740 of monochrome micro LED pixel 700 are arranged in a 2×2 array. In some embodiments, a micro LED pixel may include 9 sub-pixels, for example, arranged in a 3×3 array, or 6 sub-pixels arranged in a 2×3 array, which is not limited herein. It can be understood that in other embodiments, the at least two sub-pixels can be arranged in other forms, which is not limited herein.

For a monochrome display panel, if a probability of a single random dead pixel is 1% on monochrome display panels, with a monochrome micro LED pixel having 4 sub-pixels, the defect probability will be reduced to 10 Ppb (parts per billion).

FIG. 8 illustrates a structural diagram showing a top view of a micro LED display panel 800, according to some embodiments of the present disclosure. Referring to FIG. 8, micro LED display panel 800 includes a micro LED array 810 and an IC (integrated circuit) backplane 820. Micro LED array 810 is located on IC backplane 820 to form an image display area of micro LED display panel 800. The rest of the area on IC backplane 820 not covered by micro LED array 810 is formed as a non-functional area. IC backplane 820 is formed at the back surface of micro LED array 810 with a part extending outside of, i.e., not covered by, micro LED array 810. Micro LED array 810 includes a plurality of micro LED pixels 811 provided in an array. IC backplane 820 is configured to control the plurality of micro LED pixels 811. IC backplane 820 may include a bottom pad array (not shown) corresponding to micro LED array 810. In some embodiments, the bottom pad array includes a plurality of groups of bottom pads (for example, a group of three bottom pads including bottom pads 341, 342, and 343 in FIG. 3A), and one group of bottom pads corresponds to one micro LED pixel 811. One micro LED pixel of the plurality of micro LED pixels is electrically connected with one bottom pad group of the plurality of the groups of bottom pads.

In some embodiments, a top conductive layer of the micro LED is interconnected with respective top conductive layer of the plurality of micro LED pixels 811. That is, the top conductive layer is continuously formed on a top of micro LED array 810, and connected with every micro LED pixel 811.

In some embodiments, IC backplane 820 further includes a top connected pad 821. The top conductive layer is connected with top connected pad 821, and further may connect to an external circuit.

Each micro LED pixel herein (e.g., micro LED pixels 100, 300, 400, 500, 600, 700) has a very small volume. The micro LED pixel can be applied in a micro LED display panel. The light emitting area of the micro LED display panel, e.g., micro LED display panel 800, is very small, such as 1 mm×1 mm, 3 mm×5 mm, etc. In some embodiments, the light emitting area is the area of the micro LED array in the micro LED display panel. The micro LED display panel includes one or more micro LED pixels that form a pixel array, such as a 1600×1200, 680×480, or 1920×1080-pixel array. The diameter of each micro LED pixel is in the range of about 200 nm to 4 μm. An IC backplane, e.g., IC backplane 820, is formed at the back surface of micro LED array 810 and is electrically connected with micro LED array 810. IC backplane 820 acquires signals such as image data from outside via signal lines to control corresponding micro LED pixels 811 to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A polychrome micro LED pixel comprising at least two light emitting structures, wherein each of the at least two light emitting structures comprises at least two sub-pixels.

2. The polychrome micro LED pixel according to claim 1, wherein the at least two sub-pixels emit light with same color.

3. The polychrome micro LED pixel according to claim 2, wherein the at least two sub-pixels are controlled by the same control signal.

4. The polychrome micro LED pixel according to claim 1, wherein the at least two sub-pixels are arranged on the same horizontal plane.

5. The polychrome micro LED pixel according to claim 4, wherein each of the light emitting structures comprises four sub-pixels arranged in an array.

6. The polychrome micro LED pixel according to claim 1, wherein the at least two light emitting structures are stacked in a vertical direction.

7. The polychrome micro LED pixel according to claim 6, wherein the at least two light emitting structures are staggered in the vertical direction.

8. The polychrome micro LED pixel according to claim 6, wherein the at least two light emitting structures are overlapped in the vertical direction.

9. The polychrome micro LED pixel according to claim 6, wherein a bottom-most light emitting structure of the at least two light emitting structures emits red light, and a top-most light emitting structure of the at least two light emitting structures emits green light.

10. The polychrome micro LED pixel according to claim 1, wherein the at least two light emitting structures are arranged in a horizontal direction.

11. A micro LED display panel comprising:
an integrated circuit (IC) backplane comprising a bottom pad array, the bottom pad array comprising a plurality of groups of bottom pads; and
a micro LED array formed on the IC backplane, the micro LED array comprising a plurality of polychrome micro LED pixels, wherein each of the plurality of polychrome micro LED pixels comprises at least two light emitting structures, and each of the at least two light emitting structures comprises at least two sub-pixels;
wherein one polychrome micro LED pixel of the plurality of polychrome micro LED pixels is electrically connected with one group of bottom pads of the plurality of groups of bottom pads.

12. The micro LED display panel according to claim 11, wherein one light emitting structure corresponds to one bottom pad.

13. The micro LED display panel according to claim 12, wherein the at least two sub-pixels connect to a common one of the bottom pad.

14. A monochrome micro LED pixel, comprising at least two sub-pixels, wherein the at least two sub-pixels are controlled by the same control signal.

15. The monochrome micro LED pixel according to claim 14, wherein the at least two sub-pixels are arranged on the same horizontal plane.

16. The monochrome micro LED pixel according to claim 15, comprising four sub-pixels arranged in an array.
